(19) United States
(12) Patent Application Publication
(10) Pub. No.: US 2019/0360091 A1
(43) Pub. Date: Nov. 28, 2019

(54) VAPOR DEPOSITION MASK, VAPOR DEPOSITION APPARATUS, AND METHOD FOR PRODUCING DISPLAY DEVICE

(71) Applicant: Sharp Kabushiki Kaisha, Sakai City, Osaka (JP)

(72) Inventors: Yoshinobu MIYAMOTO, Sakai City (JP); Takeshi HIRASE, Sakai City (JP); Tohru SONODA, Sakai City (JP); Akihiro MATSUI, Sakai City (JP); Hisao OCHI, Sakai City (JP); Takashi OCHI, Sakai City (JP); Tohru SENOO, Sakai City (JP); Jumpei TAKAHASHI, Sakai City (JP)

(73) Assignee: Sharp Kabushiki Kaisha, Sakai City, Osaka (JP)

(21) Appl. No.: 16/073,817

(22) PCT Filed: Apr. 28, 2017
(86) PCT No.: PCT/JP2017/016929

§ 371 Date: Jul. 30, 2018

(51) Int. Cl. C23C 16/04

(52) U.S. Cl. CPC C23C 16/042; H01L 51/56

(57) ABSTRACT

A sheet portion and a first projection are included. The sheet portion has a sheet shape and includes one or more mask openings. The first projection is provided on a surface of the sheet portion the surface is configured to face a substrate, and the first projection has a frame shape and is formed along an edge of at least one of the one or more mask openings. With this configuration, thin films having dimensions conforming to the design dimensions and preventing blurring are formed over the substrate.

### TECHNICAL FIELD

The present disclosure relates to a vapor deposition mask, a vapor deposition apparatus, and a method for producing a display device.

### BACKGROUND ART

As a process to form thin films on a substrate, vapor deposition using a mask is known in the related art. FIG. 13 is a plan view illustrating a configuration of a CVD (chemical vapor deposition) mask used in a CVD apparatus in the related art. FIGS. 14A and 14B are cross-sectional views illustrating a configuration of a CVD apparatus 120 in the related art. As illustrated in FIG. 13, a CVD mask 110 includes a mask sheet 112 and a mask frame 111. The mask sheet 112 has a sheet shape and includes mask openings 119, and is stretched tightly on the mask frame 111, which has a frame shape.

FIG. 14A illustrates a CVD apparatus 120, in which the CVD mask 110 and a substrate 102 are positioned in place. FIG. 14B illustrates a CVD process being performed in the CVD apparatus 120. In FIGS. 14A and 14B, the CVD mask 110 is illustrated in a cross-sectional view taken along line Z-Z of FIG. 13.

The CVD mask 110 is placed on a mask holder 115, and the substrate 102 is placed on a table 121. As indicated by an arrow W1 in FIG. 14B, the table 121 is raised by a table holder 122 to bring the substrate 102 into contact with the CVD mask 110. Next, as indicated by an arrow W2, the mask sheet 112 is pressed upward by the substrate 102. Accordingly, the CVD mask 110 as a whole is raised as indicated by an arrow W3. Thus, because of the weight of the mask frame 111, the facing surfaces of the mask sheet 112 and the substrate 102 are brought into close contact with each other.

Next, a source gas 125 is introduced into the chamber of the CVD apparatus 120. The source gas 125 flows through the mask openings 119, which are formed in the mask sheet 112, to be deposited onto the surface of the substrate 102. Thus, thin films are patterned on the surface of the substrate 102.

### CITATION LIST

### Patent Literature

PTL 1: JP 2017-20068 A

### SUMMARY

### Technical Problem

The mask sheet 112 is welded at the perimeter to the mask frame 111. Thus, when pulled in the direction of the arrow W2, the mask sheet 112 slightly warps, and this results in formation of minute gaps between the facing surfaces of the mask sheet 112 and the substrate 102.

As a result, the source gas 125 flows into the spaces below the mask sheet 112, between the mask openings 119.

Consequently, as illustrated in FIG. 15, thin films 106, which are blurred with edges 106a gradually sloped, are patterned on the substrate 102.

The present disclosure has been made in view of the above circumstances in the related art. An object of the disclosure is to pattern thin films having dimensions conforming to design dimensions and preventing blurring (gradually sloped states of the edges).

### Solution to Problem

To address the issue described above, a vapor deposition mask according to an embodiment of the present disclosure is provided. The vapor deposition mask is configured to be positioned to face a substrate to form a film over the substrate. The vapor deposition mask includes a sheet portion and a first projection. The sheet portion has a sheet shape and includes at least one mask opening. The first projection is provided on a surface of the sheet portion, the surface is configured to face the substrate, and the first projection has a frame shape along an edge of the at least one of the one mask opening.

### Advantageous Effects of Invention

According to an embodiment of the present disclosure, an advantage of patterning thin films having dimensions conforming to design dimensions and preventing blurring is achieved.

### BRIEF DESCRIPTION OF DRAWINGS

FIG. 1 is a diagram illustrating a production process for organic EL display devices according to a first embodiment of the present disclosure.

FIG. 2 is a plan view of a substrate for the organic EL display devices according to the first embodiment of the present disclosure.

FIG. 3 is a cross-sectional view of an organic EL display panel formation region of the substrate of FIG. 2.

FIG. 4 is a plan view illustrating a configuration of a CVD mask according to the first embodiment of the present disclosure.

FIGS. 5A and 5B are cross-sectional views illustrating a configuration of a CVD apparatus according to the first embodiment of the present disclosure.

FIG. 6 is a diagram illustrating first inorganic films or second inorganic films patterned by the CVD apparatus illustrated in FIGS. 5A and 5B.

FIG. 7 is a plan view illustrating a configuration of a CVD mask according to a second embodiment of the present disclosure.

FIGS. 8A and 8B are cross-sectional views illustrating a configuration of a CVD apparatus according to the second embodiment of the present disclosure.

FIG. 9 is a plan view illustrating a configuration of a CVD mask according to a third embodiment of the present disclosure.

FIGS. 10A and 10B are cross-sectional views illustrating a configuration of a CVD apparatus according to the third embodiment of the present disclosure.

FIG. 11 is a plan view illustrating a configuration of a CVD mask according to a fourth embodiment of the present disclosure.

FIG. 12 is a cross-sectional view of the CVD mask according to the fourth embodiment of the present disclosure, taken along line F-F of FIG. 11.

FIG. 13 is a plan view illustrating a configuration of a CVD mask in the related art.

FIGS. 14A and 14B are cross-sectional views illustrating a configuration of a conventional CVD apparatus in the related art.

FIG. 15 is a diagram illustrating thin films patterned by the CVD apparatus illustrated in FIG. 14.

### DESCRIPTION OF EMBODIMENTS

### First Embodiment

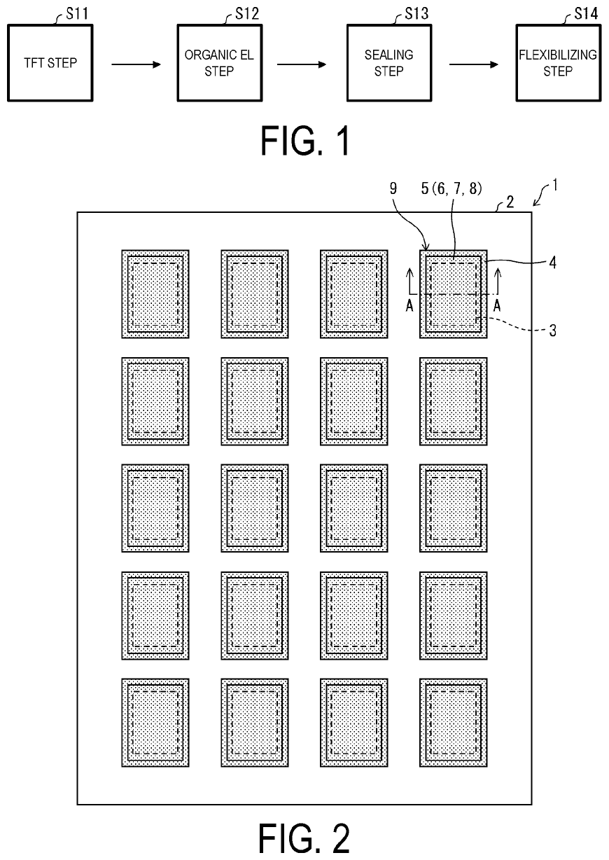

A first embodiment of the present disclosure will be described with reference to FIGS. 1 to 6.

### Outline of Method for Producing Organic EL Display Device

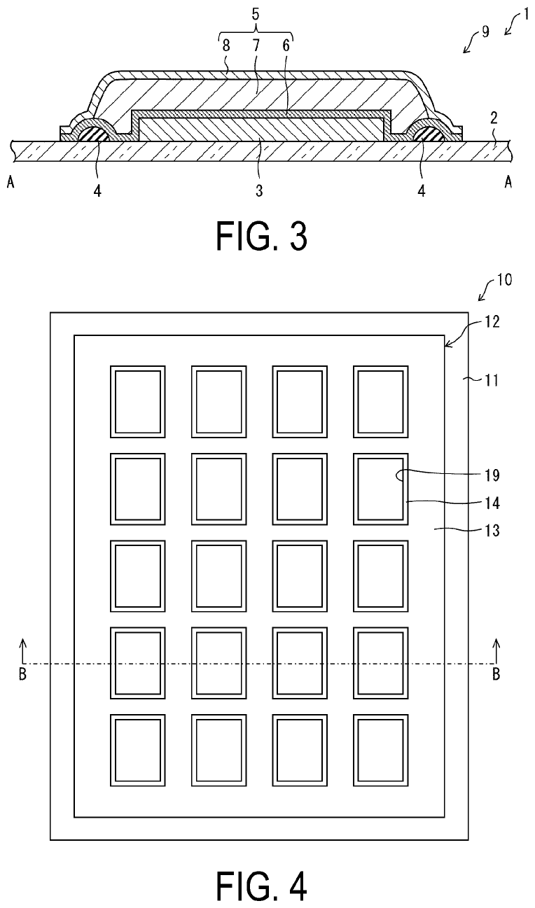

FIG. 1 is a diagram illustrating a production process for organic EL display devices according to a first embodiment of the present disclosure. FIG. 2 is a plan view of a substrate 1 for the organic EL display devices according to the first embodiment of the present disclosure. FIG. 3 is a cross-sectional view of an organic EL display panel formation region of the substrate of FIG. 2. FIG. 2 illustrates a configuration for a case where 20 organic EL display panels are to be taken from one mother glass. The number of organic EL display panels taken from one mother glass is not limited to 20, and the number may be less than or equal to 19 or greater than or equal to 21.

The substrate 1 includes 20 organic EL display panel formation regions 9. The organic EL display panel formation regions 9 are regions that are to be cut from the mother glass into discrete pieces to form organic EL display devices.

The substrate 1 includes a TFT substrate 2, pixel formation regions 3, frame-shaped banks 4, and sealing layers 5.

First, in a TFT step S11, such a TFT substrate 2 is produced. The TFT substrate 2 is produced by forming, over a mother glass, TFTs for driving the pixels (transistors and driving elements), gate lines, source lines, and various other lines by a known method, and forming, for example, a passivation film (protective film) and an interlayer insulating film (planarization film).

The passivation film prevents delamination of the metal films in the TFTs and protects the TFTs. The passivation film is formed on the mother glass or over the mother glass via another layer. The passivation film covers the TFTs. The passivation film is an inorganic insulating film including, for example, silicon nitride or silicon oxide.

The interlayer insulating film planarizes the uneven surface of the passivation film. The interlayer insulating film is formed over the passivation film. The interlayer insulating film is an organic insulating film including a photosensitive resin including, for example, an acrylic resin or a polyimide resin.

Next, in an organic EL step S12, reflective electrodes and organic EL layers are formed for the respective pixels of the TFT substrate 2. Subsequently, transparent electrodes are formed to cover the organic EL layers. The transparent electrode faces the reflective electrode across the organic EL layer. In this manner, a pixel formation region 3 for displaying images (image display region) where pixels are arranged in a matrix are formed. For each of the pixels, an organic EL element (display element) including the reflective electrode, the organic EL layer, and the transparent electrode is formed. In the process of forming the pixel formation region 3, the frame-shaped bank 4 is also formed over the TFT substrate 2. The frame-shaped bank 4 surrounds, in a manner of a frame, the pixel formation region 3. The frame-shaped bank 4 includes a photosensitive resin including, for example, an acrylic resin or a polyimide resin. By forming the frame-shaped bank 4 from an acrylic material, the film thickness can be increased to, for example, 1.0 μm or more. The frame-shaped bank 4 may be covered with an inorganic film, such as a nitride film.

Next, in a sealing step S13, the sealing layers 5 are formed. For example, the sealing layer 5 may be a triple-layer structure in which a first inorganic film 6, an organic film 7, and a second inorganic film 8 are stacked in this order. The sealing layer 5 is not limited to a triple-layer structure, and may be a stack of four or more layers.

First, over the substrate 1, transferred from the organic EL step S12, the first inorganic films 6 are formed using a CVD apparatus. The first inorganic film 6 includes, for example, silicon nitride or silicon oxide, and are formed at least on the region surrounded by the frame-shaped bank 4. The region includes the frame-shaped bank 4.

Next, using an ink-jet application apparatus, an ink material is applied to a region on the first inorganic film 6 and surrounded by the frame-shaped bank 4. The ink material includes a photosensitive material including, for example, an acrylic resin, an epoxy resin, or polyimide. The frame-shaped bank 4 serves as a bank to stop the flow of the ink material.

Next, in a leveling device, the ink-coated substrate is left to stand on a substrate mounting stage for a predetermined period of time. This allows the ink material on the substrate to flow and become flat. After passage of the predetermined period of time, UV light is directed to the ink material on the substrate from a UV source included in the leveling device. This causes the ink material to cure to form the organic film 7 on the first inorganic film 6.

Next, on the substrate, in which the organic film 7 is formed, the second inorganic film 8 is formed by the CVD apparatus to cover the organic film 7 and the first inorganic film 6. The second inorganic film 8 includes, for example, silicon nitride or silicon oxide. In this manner, the sealing layer 5, which is flat as illustrated in FIG. 3, is formed for each of the organic EL display panel formation regions 9.

The sealing layer 5 provides Thin Film Encapsulation (TFE) to seal the organic EL layers formed in the pixel formation region 3. This prevents degradation of the organic EL layers due to penetration of moisture and oxygen from the outside.

After formation of the sealing layer 5, a flexibilizing step S14 may be provided. In the flexibilizing step S14, the substrate glass is removed and, for example, a film serving as a support is applied.

Subsequently, the organic EL display panel formation regions 9 are cut to form discrete pieces. In this manner, the organic EL display devices are completed.

### CVD Mask 10 and CVD Apparatus 20

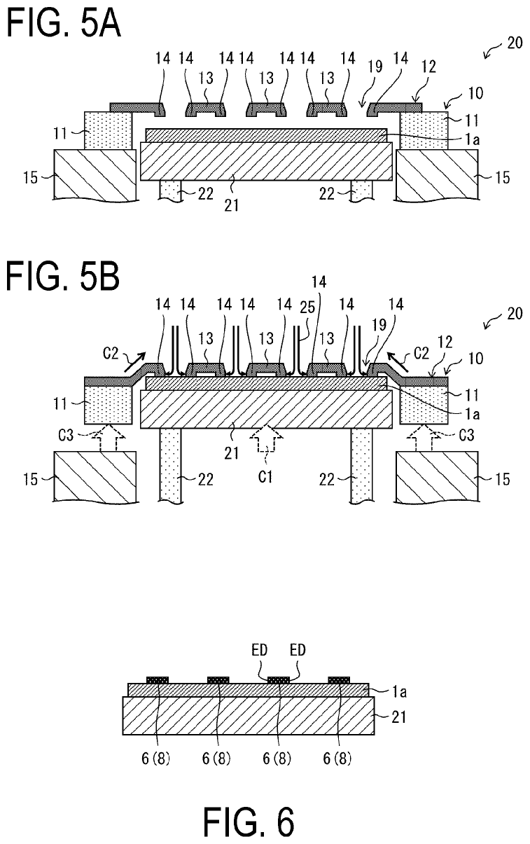

A CVD mask (vapor deposition mask) 10 and a CVD apparatus (vapor deposition apparatus) 20 will be described, mostly with reference to FIGS. 4 to 6. FIG. 4 is a plan view illustrating a configuration of the CVD mask 10 according to the first embodiment of the present disclosure. FIGS. 5A and 5B are cross-sectional views illustrating a configuration of the CVD apparatus 20 according to the first embodiment of the present disclosure.

FIG. 5A illustrates the CVD apparatus 20, in which the CVD mask 10 and a substrate 1a are positioned in place. FIG. 5B illustrates a CVD process being performed in the CVD apparatus 20. In FIGS. 5A and 5B, the CVD mask 10 is illustrated in a cross-sectional view taken along line B-B of FIG. 4. FIG. 6 is a diagram illustrating the first inorganic films 6 or the second inorganic films 8, patterned by the CVD apparatus 20 illustrated in FIGS. 5A and 5B.

The CVD mask 10 illustrated in FIGS. 4, 5A, and 5B is a mask for forming at least one of the first inorganic films 6 and the second inorganic films 8 (see FIGS. 2 and 3). In a case where the first inorganic films 6 are to be formed in the CVD apparatus 20, the substrate 1a is a substrate that has undergone the steps up to step S12 illustrated in FIG. 1. In a case where the second inorganic films 8 are to be formed, the substrate 1a is a substrate on which the films up to the organic film 7 have been formed.

The CVD mask 10 for patterning the first inorganic films 6 and the CVD mask 10 for patterning the second inorganic films 8 may be the same.

The CVD mask 10 includes a mask frame 11 and a mask sheet 12. The mask frame 11 is a frame having a frame shape. The mask sheet 12 has a sheet shape and is secured to the mask frame 11. For example, the mask sheet 12 is welded to the mask frame 11. The method for securing the mask sheet 12 to the mask frame 11 is not limited to welding. Other securing methods may also be applicable.

The mask frame 11 includes metal. The mask sheet 12 includes a sheet portion 13 and first projections 14. The mask sheet 12 is stretched tightly on the mask frame 11. The sheet portion 13 includes mask openings 19, which correspond in location and shape to the organic EL display panel formation regions 9 of the substrate 1. The area of the mask opening 19 is greater than the area of the pixel formation region 3 of the substrate 1 (see FIG. 3). In the sheet portion 13, on a surface facing the substrate 1a to be subject to CVD, the first projections 14 each having a frame shape are formed along the edges of the mask openings 19.

The sheet portion 13 may include metal, such as an invar material, or resin, such as polyimide. With regard to the thickness of the sheet portion 13, in a case where the thickness is large, edges of the first inorganic film 6 or edges of the second inorganic film 8 may be thin. Thus, the thickness of the sheet portion 13 may be as small as possible. For example, the thickness of the sheet portion 13 may range from approximately 0.1 mm to approximately 0.2 mm.

Likewise, the first projection 14 can be made of metal, such as an invar material, or resin, such as polyimide. The first projection 14 may include the same material as that of the sheet portion 13, or may include a different material from that of the sheet portion 13. The height of the first projection 14 (length from the base portion in contact with the sheet portion 13 to the top of the first projection 14) may be approximately 0.05 mm, for example.

In a case where the first projection 14 includes metal, the first projection 14 may be patterned by the etching to have a frame shape to be disposed along edges of the mask opening 19 of the sheet portion 13. In a case where the first projection 14 includes resin, the first projection 14 may be patterned by an ink-jet method to have a frame shape to be disposed along the edges of the mask opening 19 of the sheet portion 13.

The CVD apparatus 20 includes, in the chamber, a mask holder 15, a table 21, and a table holder 22. The mask holder 15 is configured to hold the CVD mask 10. The substrate 1a can be placed on the table 21. The table holder 22 is configured to raise and lower the table 21 and to hold the table 21 in such a manner that the table 21 is movable.

First, the CVD mask 10 is positioned in place on the mask holder 15 of the CVD apparatus 20 by an operator or a robot. In the first embodiment, the CVD mask 10 is placed on the mask holder 15.

When step S12 is completed, or the substrate 1a in which the organic film 7 is formed is loaded into the CVD apparatus 20, the substrate 1a is placed on the table 21 to face the bottom of the CVD mask 10. Thereafter, the relative position between the substrate 1a and the CVD mask 10 is adjusted.

Next, as indicated by an arrow C1 in FIG. 5B, the table 21 is raised by the table holder 22 not to create a gap between the substrate 1a and the mask sheet 12. Thus, the substrate 1a is brought into contact with the CVD mask 10.

Thereafter, as indicated by an arrow C2, the mask sheet 12 is pulled up by the substrate 1a, and thus the CVD mask 10 is pulled upward.

Accordingly, as indicated by an arrow C3, the CVD mask 10 as a whole is raised, and the mask frame 11 becomes separated from the mask holder 15. Then, the weight of the mask frame 11 brings the facing surfaces of the mask sheet 12 and the substrate 1a into close contact with each other.

Next, a source gas 25, for example, silicon nitride, to be formed into the first inorganic films 6 or the second inorganic films 8 is introduced into the chamber of the CVD apparatus 20. Thus, the source gas 25 travels through the mask openings 19, which are formed in the mask sheet 12, to be deposited onto the surface of the substrate 1a.

The mask openings 19 of the CVD mask 10 are positioned to face the pixel formation regions 3, which are formed on the substrate 1a. The area of the mask openings 19 is greater than the area of the pixel formation regions 3.

Thus, the first inorganic films 6, for the respective pixel formation regions 3 of the substrate 1a, are patterned over the pixel formation regions 3, or the second inorganic films 8, for the respective pixel formation regions 3, are patterned over the pixel formation regions 3, via the organic film 7.

The facing surfaces of the sheet portion 13 and the substrate 1a are substantially in contact with each other. However, the sheet portion 13 has a small thickness, namely, from approximately 0.1 mm to approximately 0.2 mm, and the perimeter is welded to the mask frame 11. Thus, when pulled in the direction indicated by the arrow C2, the sheet portion 13 might be warped only slightly and minute gaps might occur between the facing surfaces of the mask sheet 12 and the substrate 1a.

However, the mask sheet 12 includes the first projections 14 formed on the surface configured to face the substrate 1a. The first projections 14 are shaped to be disposed along the edges of the mask openings 19. The first projections 14 serves as walls for preventing the source gas 25 from flowing into spaces below the mask sheet 12, between the mask openings 19.

This configuration prevents deposition of the source gas 25 on regions other than the formation regions for the first inorganic films 6 or the second inorganic films 8 over the substrate 1a.

Thus, this enables patterning of thin films, such as the first inorganic films 6 or the second inorganic films 8, having edges ED, which are substantially perpendicular to the substrate surface, as illustrated in FIG. 6. That is, this enables patterning of thin films, such as the first inorganic films 6 or the second inorganic films 8, having dimensions conforming to the design dimensions and preventing blurring (gradually sloped states of the edges ED).

As a result, as illustrated in FIG. 3, the sealing layer 5 has dimensions conforming to the design dimensions, and prevents blurring.

### MODIFIED EXAMPLE

The CVD mask 10 for forming the first inorganic films 6 and the CVD mask 10 for forming the second inorganic films 8 may be different from each other.

In this case, it may be preferable that the area defined by the first projection 14 of the CVD mask 10 for forming the second inorganic films 8 be greater than the area defined by the first projection 14 of the CVD mask 10 for forming the first inorganic films 6. Here, the areas each refer to the area surrounded by the frame. Furthermore, the area of the mask openings 19 of the CVD mask 10 for patterning the second inorganic films 8 may be equal to the area of the mask openings 19 of the CVD mask 10 for patterning the first inorganic films 6.

This configuration prevents, in patterning the second inorganic films 8, the first projections 14 of the CVD mask 10 for patterning the second inorganic films 8 from contacting the first inorganic films 6, which have already been patterned on the substrate 1a. This reduces a possibility of cracking in the first inorganic films 6, and thus seals the display elements in a more stable manner.

Furthermore, the area of the mask openings 19 of the CVD mask 10 for patterning the second inorganic films 8 is equal to the area of the mask openings 19 of the CVD mask 10 for patterning the first inorganic films 6. This eliminates the need to increase the area of the non-display area (region outside the pixel formation region 3) to form the organic EL display device.

### Second Embodiment

A second embodiment of the present disclosure will be described below. For convenience of description, members whose functions are identical to those of the members described in the first embodiment are given the same reference characters, and their descriptions are omitted here.

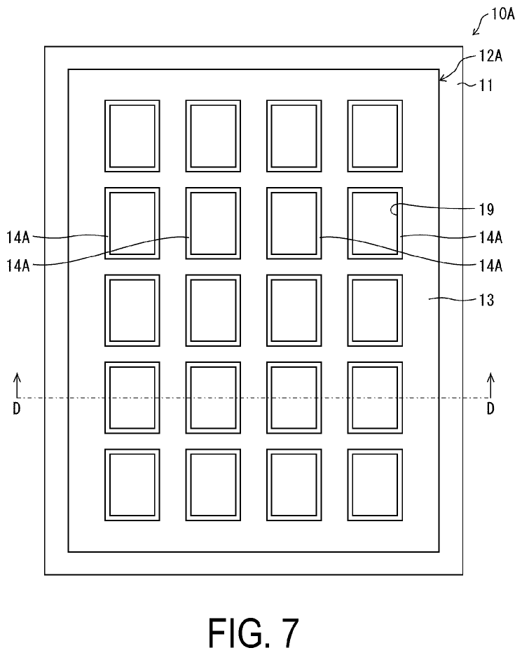

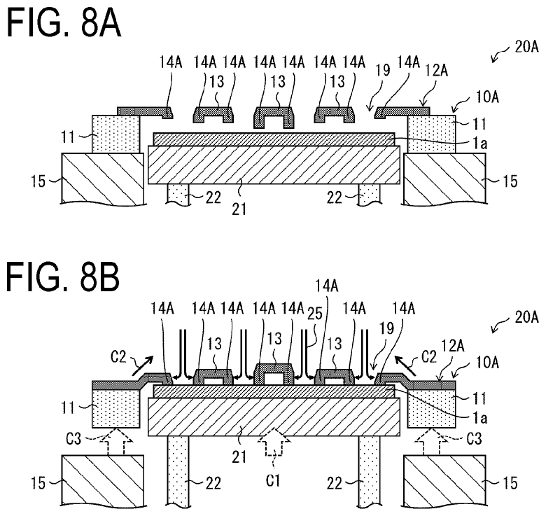

FIG. 7 is a plan view illustrating a configuration of a CVD mask 10A according to a second embodiment of the present disclosure. FIGS. 8A and 8B are cross-sectional views illustrating a configuration of a CVD apparatus 20A according to the second embodiment of the present disclosure. FIG. 8A illustrates the CVD apparatus 20A, in which the CVD mask 10A and the substrate 1a are positioned in place. FIG. 8B illustrates a CVD process being performed in the CVD apparatus 20A. In FIGS. 8A and 8B, the CVD mask 10A is illustrated in a cross-sectional view taken along line D-D of FIG. 7.

The CVD mask 10A includes a mask sheet 12A in place of the mask sheet 12, which is included in the CVD mask 10 (see FIGS. 4, 5A, and 5B). The mask sheet 12A includes first projections 14A in place of the first projections 14, which are included in the mask sheet 12. The other constituents of the CVD mask 10A are the same as those of the CVD mask 10.

The first projections 14A are formed in the sheet portion 13, on the surface configured to face the substrate 1a to be subject to CVD. The first projection 14A is formed to have a frame shape to be disposed along edges of each of the mask openings 19. The first projections 14A each are gradually higher towards the center of the CVD mask 10A from opposite ends of the CVD mask 10A.

In the second embodiment, the first projections 14A are configured such that the first projections 14A are gradually higher towards the center of the CVD mask 10A from the opposite ends of the CVD mask 10A, both in the longitudinal direction (vertical direction in FIG. 7) and in the lateral direction (lateral direction in FIG. 7) that is orthogonal to the longitudinal direction.

The CVD apparatus 20A includes the CVD mask 10A in place of the CVD mask 10. The other constituents of the CVD apparatus 20A are the same as those of the CVD apparatus 20.

First, the CVD mask 10A is positioned in place on the mask holder 15 of the CVD apparatus 20A by an operator or a robot. In the second embodiment, the CVD mask 10A is placed on the mask holder 15.

When step S12 is completed, or the substrate 1a, in which the organic film 7 is formed, is loaded into the CVD apparatus 20A, the substrate 1a is placed on the table 21 to face the bottom of the CVD mask 10A. Thereafter, the relative position between the substrate 1a and the CVD mask 10A is adjusted.

Next, as indicated by the arrow C1 in FIG. 8B, the table 21 is raised by the table holder 22 not to create a gap between the substrate 1a and the mask sheet 12A. Thus, the substrate 1a is brought into contact with the CVD mask 10A.

Thereafter, as indicated by the arrow C2, the mask sheet 12A is pulled up by the substrate 1a, and thus the CVD mask 10A is pulled upward.

Accordingly, as indicated by the arrow C3, the CVD mask 10A as a whole is raised, and the mask frame 11 becomes separated from the mask holder 15. The weight of the mask frame 11 brings the facing surfaces of the mask sheet 12A and the substrate 1a into close contact with each other.

Next, the source gas 25 is introduced into the chamber of the CVD apparatus 20A. The source gas 25 flows through the mask openings 19, which are formed in the mask sheet 12A, to be deposited onto the surface of the substrate 1a. Thus, the first inorganic films 6 or the second inorganic films 8 are patterned on the surface of the substrate 1a.

The facing surfaces of the sheet portion 13 and the substrate 1a are substantially in contact with each other. However, the sheet portion 13 is welded at the perimeter to the mask frame 11. Thus, when pulled in the direction indicated by the arrow C2, the sheet portion 13 might be warped only slightly, and minute gaps might occur between the facing surfaces of the sheet portion 13 and the substrate 1a.

In particular, since the sheet portion 13 is welded at the perimeter to the mask frame 11, the sheet portion 13 bulges more easily at a middle region than at an end region. Thus, the gap between the sheet portion 13 and the substrate la tends to be larger at a middle region of the sheet portion 13 than at an end region.

However, the mask sheet 12A includes the first projections 14A, which is formed on the surface configured to face the substrate 1a. The first projections 14A are shaped to be disposed along the edges of the mask openings 19. The first projections 14A are each gradually higher towards the center of the CVD mask 10A from the opposite ends of the CVD mask 10A.

Thus, the first projections 14A sufficiently serve as walls for preventing the source gas 25 from flowing into spaces below the mask sheet 12A, between the mask openings 19, even in a middle region of the sheet portion 13, where the gap between the sheet portion 13 and the substrate 1a particularly tends to be large.

This configuration sufficiently prevents, over the substrate 1a, the source gas 25 from being deposited on regions other than the formation regions for the first inorganic films 6 or the second inorganic films 8, even in a middle region of the substrate 1a, where the source gas 25 particularly tends to be deposited.

Hence, over the entire surface of the substrate 1a, the first inorganic films 6 or the second inorganic films 8, which has dimensions conforming to the design dimensions and which prevents blurring, are patterned.

Consequently, as illustrated in FIG. 3, the sealing layers 5, which has dimensions conforming to the design dimensions and which prevents blurring, are formed over the entire surface of the substrate 1.

The first projections 14A each may be preferably gradually higher towards the center of the CVD mask 10A from the opposite ends, both in the longitudinal direction and in the lateral direction. With this configuration, deposition of the source gas 25 on regions other than the formation regions for the first inorganic films 6 or the second inorganic films 8 is more reliably prevented, in a middle region where the source gas 25 tends to be deposited.

The first projections 14A each may be gradually higher towards the center of the CVD mask 10A from the opposite ends, either in the longitudinal direction or in the lateral direction. This configuration also provides the effect of preventing the source gas 25 from being deposited on regions other than the formation regions for the first inorganic films 6 or the second inorganic films 8, in a middle region, where the source gas 25 tends to be deposited.

### Third Embodiment

A third embodiment of the present disclosure will be described below. For convenience of description, members whose functions are identical to those of the members described in the first and second embodiments are given the same reference characters, and their descriptions are omitted here.

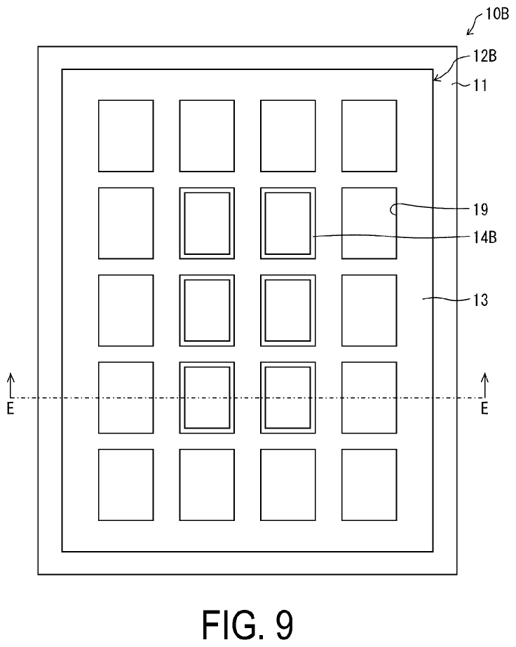

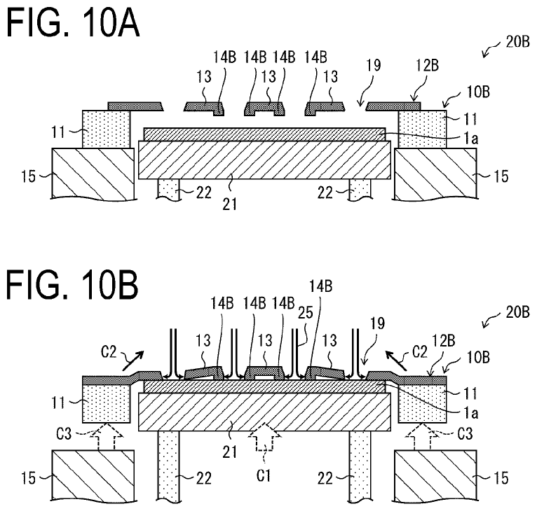

FIG. 9 is a plan view illustrating a configuration of a CVD mask 10B according to a third embodiment of the present disclosure. FIGS. 10A and 10B are cross-sectional views illustrating a configuration of a CVD apparatus 20B according to the third embodiment of the present disclosure. FIG. 10A illustrates the CVD apparatus 20B, in which the CVD mask 10B and the substrate 1a are positioned in place. FIG. 10B illustrates a CVD process being performed in the CVD apparatus 20B. In FIGS. 10A and 10B, the CVD mask 10B is illustrated in a cross-sectional view taken along line E-E of FIG. 9.

The CVD mask 10B includes a mask sheet 12B in place of the mask sheet 12, which is included in the CVD mask 10 (see FIGS. 4, 5A, and 5B). The mask sheet 12B includes a first projection 14B in place of the first projection 14, which is included in the mask sheet 12. The other constituents of the CVD mask 10B are the same as those of the CVD mask 10.

The first projection 14B is formed to have a frame shape to be disposed along edges of each of the mask openings 19, in the sheet portion 13, on the surface configured to face the substrate 1a to be subject to CVD. The first projections 14B are formed along edges of the mask openings 19 located in a middle region of the sheet portion 13, whereas the first projections 14B are not formed along the edge of any of the mask openings 19 at ends of the sheet portion 13.

In the third embodiment, the first projections 14B are not formed along the edges of outermost mask openings 19 arranged in a frame shape, in all mask openings 19 defined in the sheet portion 13, whereas the first projections 14B are formed along the edges of six mask openings 19 located in the middle region surrounded by such outermost mask openings 19 arranged in a frame shape. The shape and the material of each of the first projections 14B are the same as the shape and the material of the first projection 14 (see FIGS. 4, 5A, and 5B).

The CVD apparatus 20B includes the CVD mask 10B in place of the CVD mask 10 (see FIGS. 4, 5A, and 5B). The other constituents of the CVD apparatus 20B are the same as those of the CVD apparatus 20.

First, the CVD mask 10B is positioned in place on the mask holder 15 of the CVD apparatus 20B by an operator or a robot. In the third embodiment, the CVD mask 10B is placed on the mask holder 15.

When step S12 is completed, or the substrate 1a, in which the organic film 7 is formed, is loaded into the CVD apparatus 20B, the substrate 1a is placed on the table 21 to face the bottom of the CVD mask 10B. Thereafter, the relative position between the substrate 1a and the CVD mask 10B is adjusted.

Next, as indicated by the arrow C1 in FIG. 10B, the table 21 is raised by the table holder 22 not to create a gap between the substrate 1a and the mask sheet 12B. Thus, the substrate 1a is brought into contact with the CVD mask 10B.

Thereafter, as indicated by the arrow C2, the mask frame 11 is pulled up by the substrate 1a to push the CVD mask 10B upward.

Accordingly, as indicated by the arrow C3, the CVD mask 10B as a whole is raised, and the mask frame 11 becomes separated from the mask holder 15. The weight of the mask sheet 12B brings the facing surfaces of the mask sheet 12B and the substrate 1a into close contact with each other.

Next, the source gas 25 is introduced into the chamber of the CVD apparatus 20B. The source gas 25 flows through the mask openings 19, which are formed in the mask sheet 12B, to be deposited onto the surface of the substrate 1a. Thus, the first inorganic films 6 or the second inorganic films 8 are patterned on the surface of the substrate 1a.

In the mask sheet 12B, on the surface configured to face the substrate 1a, the first projections 14B are not formed along the edges of the mask openings 19 on the end of the sheet portion 13, whereas the first projections 14B are formed along the edges of the mask openings 19 formed in a middle region of the sheet portion 13.

Thus, the first projections 14B sufficiently serve as walls for preventing the source gas 25 from flowing into spaces below the mask sheet 12B, between the mask openings 19, even in a middle region of the sheet portion 13, where the gap between the sheet portion 13 and the substrate 1a particularly tends to be large.

This configuration sufficiently prevents, over the substrate 1a, the source gas 25 from being deposited on regions other than the formation regions for the first inorganic films 6 or the second inorganic films 8, even in a middle region of the substrate 1a, where the source gas 25 particularly tends to be deposited.

As a result, over the entire surface of the substrate 1a, the first inorganic films 6 or the second inorganic films 8, which has dimensions conforming to the design dimensions and which prevents blurring, are patterned.

Consequently, as illustrated in FIG. 3, the sealing layers 5, which have dimensions conforming to the design dimensions and which prevent blurring, are formed over the entire surface of the substrate 1.

In the third embodiment, the first projections 14B are not formed along the edges of the outermost mask openings 19 arranged in a frame shape in the sheet portion 13, whereas the first projections 14B are formed along the edges of six mask openings 19 located in a middle region surrounded by the outermost mask openings 19 arranged in a frame shape.

With this configuration, deposition of the source gas 25 on regions other than the formation regions for the first inorganic films 6 or the second inorganic films 8 is more reliably prevented, in a middle region where the source gas 25 tends to be deposited.

The first projections 14B may not be necessarily formed along the edges of outermost mask openings 19 in the mask openings defined in the sheet portion 13, or may not be necessarily formed in several rows and lines of mask openings 19 including the outermost mask openings 19 arranged in a frame shape, but the first projections 14B may be formed in a frame shape along the edges of one or more mask openings 19 located in a middle region surrounded by the mask openings 19 arranged in a frame shape.

In a case where the sheet portion 13 has four rows of the mask openings 19 in the longer side direction, the first projections 14B may not be necessarily formed along the edges of the mask openings 19 disposed in two rows on end sides, but may be formed in a frame shape along the edges of the mask openings 19 disposed in two rows in the middle portion between the two rows on the end sides.

In a case where the sheet portion 13 has five rows of the mask openings 19 in the shorter side direction, the first projection 14B may not be formed along the edges of those of the mask openings 19 that are disposed in the two outer end rows, and may be formed, in a frame shape, along the edges of those of the mask openings 19 that are disposed in the three middle rows between the two outer end rows.

This configuration also provides an effect of preventing the source gas 25 from being deposited on regions other than the formation regions for the first inorganic films 6 or the second inorganic films 8, in a middle region where the source gas 25 tends to be deposited.

### Fourth Embodiment

A fourth embodiment of the present disclosure will be described below. For convenience of description, members whose functions are identical to those of the members described in the first to third embodiments are given the same reference characters, and their descriptions are omitted here.

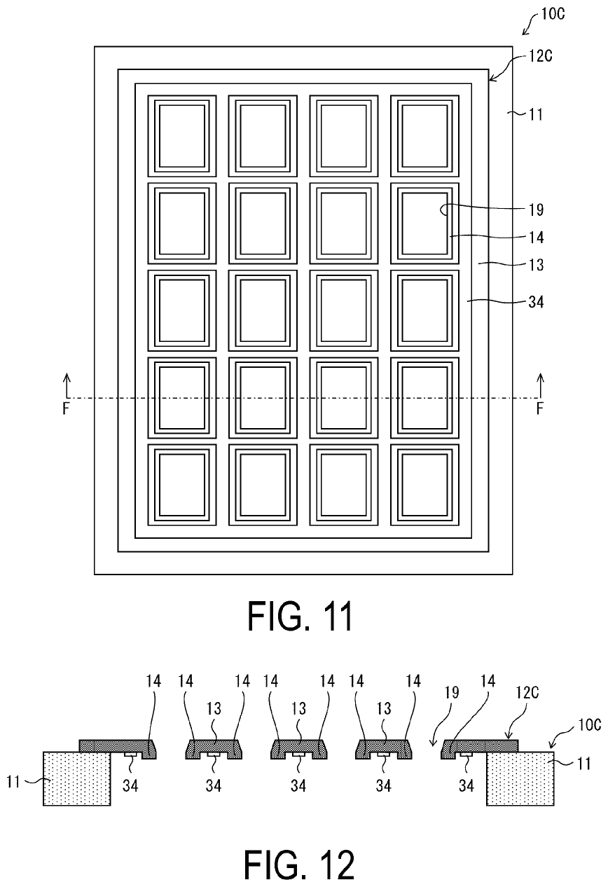

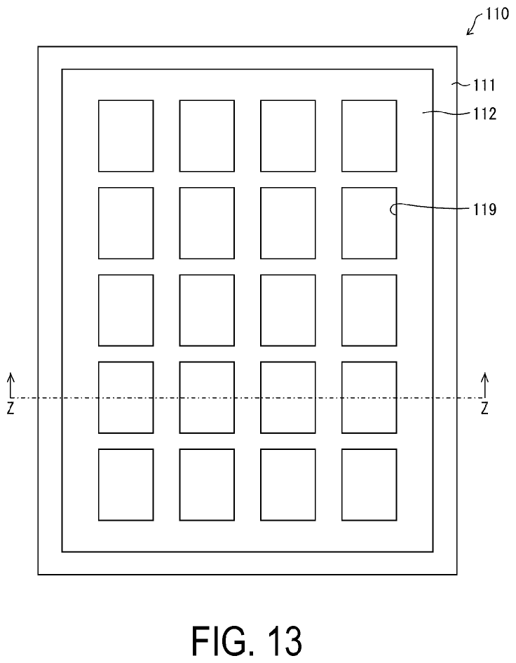

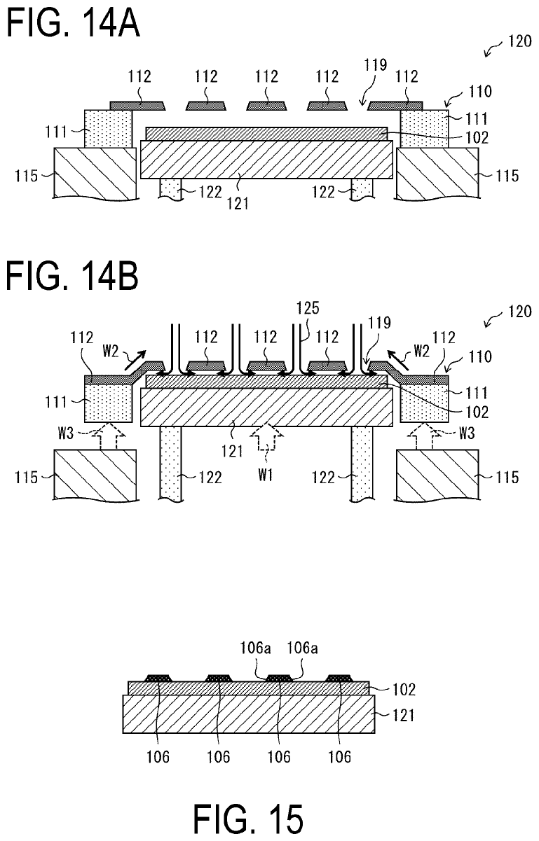

FIG. 11 is a plan view illustrating a configuration of a CVD mask 10C according to a fourth embodiment of the present disclosure. FIG. 12 is a cross-sectional view of the CVD mask 10C according to the fourth embodiment of the present disclosure, taken along line F-F of FIG. 11.

The CVD mask 10C includes a mask sheet 12C in place of the mask sheet 12, which is included in the CVD mask 10 (see FIGS. 4, 5A, and 5B). The mask sheet 12C is similar to the mask sheet 12, but the mask sheet 12C includes a second projection 34. The other constituents of the CVD mask 10C are the same as those of the CVD mask 10.

The second projection 34 is formed on the sheet portion 13, on the surface configured to face the substrate 1a to be subject to CVD. The second projection 34 is in a lattice and is spaced from the edges of the mask openings 19. In other words, the second projection 34 is spaced from the first projections 14 and surround the first projections 14. This increases the rigidity of the mask sheet 12C. This makes it difficult for the sheet portion 13 to ward in CVD processing, and thus prevents gaps from occurring between the facing surfaces of the sheet portion 13 and the substrate 1a. Thus, the source gas 25 is prevented from flowing into spaces below the mask sheet 12C between the mask openings 19. As a result, over the entire surface of the substrate 1a, the first inorganic films 6 or the second inorganic films 8, which has dimensions conforming to the design dimensions and which prevents blurring, is patterned.

Consequently, as illustrated in FIG. 3, the sealing layers 5, which have dimensions conforming to the design dimensions and which prevent blurring, are formed over the entire surface of the substrate 1.

The height of the second projection 34 is lower than the height of the first projection 14. This configuration prevents the second projection 34 from contacting the substrate 1a in CVD processing. As a result, a defect that may occur due to the second projection 34 contacting the substrate 1a is prevented. In addition, formation of gaps between the first projections 14 and the substrate 1a is prevented.

The material of the second projection 34, as with the first projection 14, may include metal, such as an invar material, or resin, such as polyimide.

In a case where the second projection 34 includes metal, the second projection 34 may be patterned by the etching to be in a lattice surrounding the mask openings 19 of the sheet portion 13. In a case where the second projection 34 includes resin, the second projection 34 may be patterned by an ink-jet method to be in a lattice surrounding the mask openings 19 of the sheet portion 13.

The second projection 34 may be provided in the CVD mask 10A (see FIGS. 7, 8A, and 8B) or in the CVD mask 10B (see FIGS. 9, 10A, and 10B), rather than in the CVD mask 10 (see FIGS. 4, 5A, and 5B).

In a case where the second projection 34 is provided in the CVD mask 10A (see FIGS. 7, 8A, and 8B), the height of the second projection 34 is made lower than the height of the lowest first projections 14, which are disposed adjacent to the outer perimeter.

### Supplement

A vapor deposition mask according to a first aspect of the present disclosure is configured to be positioned to face a substrate to form a film over the substrate. The vapor deposition mask includes a sheet and a first projection. The sheet has a sheet shape and includes one or more mask openings. The first projection is formed on a surface of the sheet, the surface is configured to face the substrate, and the first projection has a frame shape and is formed along an edge of at least one of the one or more mask openings.

With the configuration described above, in the formation of films over the substrate, the first projection serves as a wall for preventing a source gas from flowing into spaces between areas between the mask openings in the vapor deposition mask and the substrate. Accordingly, thin films having dimensions conforming to the design dimensions and preventing blurring (gradually sloped states of the edges) are formed over the substrate.

According to a second aspect of the present disclosure, in the vapor deposition mask in the first aspect, a plurality of mask openings may be provided in the sheet, and the first projection may have the frame shape along an edge of each of the plurality of mask openings. With this configuration, thin films having dimensions conforming to the design dimensions and preventing blurring are formed over the entire substrate.

According to a third aspect of the present disclosure, in the vapor deposition mask of the first aspect, a plurality of mask openings may be provided. The first projection may not be provided along an edge of at least a part of the plurality of mask openings located at an end of the sheet.

According to a fourth aspect of the present disclosure, in the vapor deposition mask of the third aspect, the at least one mask opening in the sheet may be arranged in a matrix. The first projection may not be provided at any of the plurality of mask openings arranged in a frame shape at an outermost periphery, and the first projection may be provided to have the frame shape along an edge of the at least one mask opening, the at least one mask opening being provided in a region surrounded by the plurality of mask openings arranged in the frame shape at the outermost periphery.

According to a fifth aspect of the present disclosure, in the vapor deposition mask of any one of the first to fourth aspects, a plurality of mask openings and a plurality of first projections may be provided in the sheet, and in the plurality of first projections, the heights of the plurality of first projections may be greater towards the center part of the sheet from an outermost periphery of the sheet.

With this configuration, thin films having dimensions conforming to the design dimensions and preventing blurring are formed, even in a middle region of the substrate, where a gap readily forms between the sheet and the substrate and a source gas easily flows into the gap.

According to a sixth aspect of the present disclosure, the vapor deposition mask of any one of the first to fifth aspects may further include a second projection provided on the surface of the sheet, the surface being configured to face the substrate, the second projection being in a lattice to be spaced from the first projection.

With this configuration, the rigidity of the sheet is increased. This reduces the possibility of warping of the sheet, and thus prevents gaps from occurring between the facing surfaces of the sheet and the substrate. Accordingly, thin films having dimensions conforming to the design dimensions and preventing blurring, to a greater extent, are formed.

According to a seventh aspect of the present disclosure, in the vapor deposition mask of the sixth aspect, the second projection may have a height smaller than a height of the first projection. This prevents the second projection of the vapor deposition mask from contacting the substrate. This prevents a defect that may occur due to the second projection contacting the substrate. In addition, this prevents formation of gaps between the first projections and the substrate is prevented.

According to an eighth aspect of the present disclosure, the vapor deposition mask of any one of the first to seventh aspects may further include a mask frame having a frame shape, and an edge of the sheet may be secured to the mask frame.

According to a ninth aspect of the present disclosure, a vapor deposition apparatus may include the vapor deposition mask according to any one of the first to eighth aspects.

According to a tenth aspect of the present disclosure, a method for producing a display device may include using a substrate including a film formed with the vapor deposition mask according to any one of the first to eighth aspects.

According to an eleventh aspect of the present disclosure, the method of the tenth aspect may further include forming a first inorganic film, in the substrate, for each of a plurality of image display regions including a plurality of display elements arranged in a matrix, directly on the plurality of image display regions; and forming a second inorganic film, for each of the plurality of image display regions, on each of the plurality of image display regions via an organic film, and at least one of the forming of the first inorganic film and the forming of the second inorganic film is performed by using the vapor deposition mask.

According to a twelfth aspect of the present disclosure, in the eleventh aspect, the one or more mask openings of the vapor deposition mask may have an area greater than an area of the plurality of image display regions.

With this configuration, at least one of the first inorganic films and the second inorganic films, for the respective image display regions, are formed.

According to a thirteenth aspect of the present disclosure, in the method of the eleventh aspect or the twelfth aspect, the first projection of the vapor deposition mask configured to form the second inorganic film may define an area surrounded by the frame shape greater than an area defined by the first projection of the vapor deposition mask configured to form the first inorganic films surrounded by the frame shape.

This configuration prevents, in forming the second inorganic films, the first projection of the vapor deposition mask for forming the second inorganic films from contacting the first inorganic films that have been formed on the substrate. This reduces a possibility of cracking in the first inorganic films, and thus seals, in a more stable manner, the display elements formed in the image display regions.

According to a fourteenth aspect of the present disclosure, in the method of the thirteenth aspect, the mask openings of the vapor deposition mask configured to form the second inorganic films may have an area equal to an area of the mask openings of the vapor deposition mask configured to form the first inorganic films.

This configuration enables formation of the display device without increasing the area of the non-display area (region outside the image display region).

The present disclosure is not limited to each of the embodiments stated above, and various modifications may be implemented within a range not departing from the scope of the claims. Embodiments obtained by appropriately combining technical approaches stated in each of the different embodiments also fall within the scope of the technology of the present disclosure. Moreover, novel technical features may be formed by combining the technical approaches stated in each of the embodiments.

### REFERENCE SIGNS LIST

1, 1a Substrate
2 TFT substrate
3 Pixel formation region (image display region)
4 Frame-shaped bank
5 Sealing layer
6 First inorganic film (inorganic film)
8 Second inorganic film (inorganic film)
7 Organic film
9 Organic EL display panel formation region
10, 10A, 10B, 10C CVD mask (vapor deposition mask)
11 Mask frame
12, 12A, 12B, 12C Mask sheet
12 Organic EL step S
13 Sheet portion
14, 14A, 14B First projection
15 Mask holder
19 Mask opening
20, 20A, 20B CVD apparatus (vapor deposition apparatus)
21 Table
22 Table holder
25 Source gas
34 Second projection

1-4. (canceled)

5. A vapor deposition mask configured to be positioned to face a substrate and configured to form a film over the substrate, the vapor deposition mask comprising:
a sheet portion having a sheet shape and including a plurality of mask openings; and
a plurality of first projections first projection provided on a surface of the sheet portion, the surface being configured to face the substrate, each of the plurality of first projections having a frame shape along an edge of the at least one of the plurality of mask openings,
wherein
in the plurality of first projections, the heights of the plurality of first projections are greater towards the center part of the sheet portion from an outermost periphery of the sheet portion.

6. A vapor deposition mask configured to be positioned to face a substrate and configured to form a film over the substrate, the vapor deposition mask comprising:
a sheet portion having a sheet shape and including at least one mask opening;
a first projection formed on a surface of the sheet portion, the surface being configured to face the substrate, the first projection having a frame shape along an edge of at least one of the at least one mask opening; and
a second projection provided on the surface of the sheet portion, the surface being configured to face the substrate, the second projection being in a lattice to be spaced from the first projection.

7. The vapor deposition mask according to claim 6,
wherein the second projection has a height smaller than a height of the first projection.

8-14. (canceled)

15. The vapor deposition mask according to claim 5, further comprising a second projection provided on the surface of the sheet portion, the surface being configured to face the substrate, the second projection being in a lattice to be spaced from the first projection.

16. The vapor deposition mask according to claim 15,
wherein the second projection has a height lower than a height of the first projection.

17. The vapor deposition mask according to claim 5,
wherein each of the plurality of first projections has the frame shape along an edge of each of the plurality of mask openings.

18. The vapor deposition mask according to claim 6,
wherein a plurality of mask openings are provided in the sheet portion, and
the first projection has a frame shape along an edge of each of the plurality of mask openings.

19. The vapor deposition mask according to claim 5,
wherein the plurality of first projections are not provided along an edge of at least a part of the plurality of mask openings located at an end of the sheet portion.

20. The vapor deposition mask according to claim 6,
wherein a plurality of mask openings are provided in the sheet portion, and
the first projection is not formed along an edge of at least a part of the plurality of mask openings located at an end of the sheet portion.

21. The vapor deposition mask according to claim 19,
wherein the plurality of mask openings in the sheet portion are arranged in a matrix,
the plurality of first projections are not provided at any of the plurality of mask openings arranged in a frame shape at an outermost periphery, and
the plurality of first projections are respectively provided to have the frame shape along edges of the plurality of mask openings, the plurality of mask openings being provided in a region surrounded by the plurality of mask openings arranged in the frame shape at the outermost periphery.

22. The vapor deposition mask according to claim 20,
wherein the plurality of mask openings in the sheet portion are arranged in a matrix,
the plurality of first projections are not provided at any of the plurality of mask openings arranged in a frame shape at an outermost periphery, and
the plurality of first projections are respectively provided to have the frame shape along edges of the plurality of mask openings, the plurality of mask openings being provided in a region surrounded by the plurality of mask openings arranged in the frame shape at the outermost periphery.

23. The vapor deposition mask according to claim 5,
further comprising a mask frame having a frame shape, and an edge of the sheet portion is secured to the mask frame.

24. The vapor deposition mask according to claim 6,
further comprising a mask frame having a frame shape, and an edge of the sheet portion is secured to the mask frame.

25. A vapor deposition apparatus comprising the vapor deposition mask according to claim 5.

26. A vapor deposition apparatus comprising the vapor deposition mask according to claim 6.

27. A method for producing a display device, the method comprising using a substrate comprising a film formed with the vapor deposition mask according to claim 5.

28. A method for producing a display device, the method comprising using a substrate comprising a film formed with the vapor deposition mask according to claim 6.
